(19) United States
(12) Patent Application Publication
(10) Pub. No.: US 2025/0219582 A1
(43) Pub. Date: Jul. 3, 2025

(54) ELECTRONIC DEVICE INCLUDING A COMMUNICATION DEVICE OPERATING BASED ON A GENERALIZED RESIDUAL, AND OPERATION METHOD OF A CHARACTERISTIC ANALYSIS DEVICE GENERATING THE GENERALIZED RESIDUAL

(71) Applicant: Samsung Electronics Co., Ltd., Suwon-si (KR)

(72) Inventors: Dongkwon Choi, Suwon-si (KR); YOUNGKI LEE, Suwon-si (KR); HONGKOO LEE, Suwon-si (KR); WONCHEOL JEONG, Suwon-si (KR); Joonhoi Hur, Suwon-si (KR)

(21) Appl. No.: 18/963,627

(22) Filed: Nov. 28, 2024

(30) Foreign Application Priority Data
Dec. 29, 2023 (KR) 10-2023-0196957
May 3, 2024 (KR) 10-2024-0059261

(51) Int. Cl. H03F 1/02; H03F 3/19; H03G 3/30

(52) U.S. Cl. CPC H03F 1/0205; H03F 3/19; H03G 3/3036; H03G 2201/103

(57) ABSTRACT

A communication device may comprise an amplifier providing, to an antenna, an amplified input signal generated by amplifying an input signal of target frequency, a power detector circuit generating a detected power value by detecting power of the amplified input signal, a memory circuit configured to store first and second representative correction value corresponding to first frequency and second representative frequency, respectively, an interpolation circuit calculating, based on the first and second representative correction value, a first interpolation correction value corresponding to the target frequency, a residual compensation circuit reading a first generalized residual corresponding to the target frequency from an external memory device and to generate a first compensation correction value based on the first generalized residual and the first interpolation correction value, and a gain control circuit controlling a gain of the amplifier based on the first compensation correction value.

### CROSS-REFERENCE TO RELATED APPLICATION(S)

This application claims priority and the benefit under 35 U.S.C. § 119 to and of Korean Patent Application No. 10-2023-0196957, filed in the Korean Intellectual Property Office on Dec. 29, 2023, and Korean Patent Application No. 10-2024-0059261, filed in the Korean Intellectual Property Office on May 3, 2024, the entire contents of both of which are incorporated herein by reference.

### BACKGROUND

### (a) Field of the Invention

The present disclosure relates to a wireless communication device. More specifically, the present disclosure relates to an electronic device including a communication device operating based on generalized residuals, and an operation method of a characteristic analysis device that generates generalized residuals.

### (b) Description of the Related Art

As wireless communication technology advances, the frequencies used by communication devices are getting higher and higher to increase data throughput. However, the higher the frequency used by the communication device, the higher the transmission losses that occur in wireless communication. Accordingly, it is becoming increasingly important to adjust the magnitude of the power emitted through the antenna in consideration of the transmission loss that occurs during wireless communication.

In particular, the power consumption of a wireless communication device may increase unnecessarily when the communication device excessively increases the magnitude of the power emitted through the antenna. On the other hand, when the communication device excessively reduces the magnitude of power emitted through the antenna, there may be problems with wireless communication due to transmission loss.

### SUMMARY

The present disclosure is for solving the above-described technical problem. More specifically, the purpose of the present disclosure is to provide a communication device for adjusting the size of output power emitted through an antenna based on a generalized residual, an electronic apparatus including the communication device, and an operation method of a characteristic analysis device generating the generalized residual.

In an embodiment, a communication device controlling an antenna may be provided. The communication device may comprise: an amplifier configured to provide, to the antenna, an amplified input signal generated by amplifying an input signal having a target frequency; a power detector circuit configured to generate a detected power value by detecting a power of the amplified input signal; a memory circuit configured to store a first representative correction value and a second representative correction value corresponding to a first representative frequency and a second representative frequency, respectively; an interpolation circuit configured to calculate, based on the first representative correction value and the second representative correction value, a first interpolation correction value corresponding to the target frequency; a residual compensation circuit configured to read a first generalized residual corresponding to the target frequency from an external memory device and to generate a first compensation correction value based on the first generalized residual and the first interpolation correction value; and a gain control circuit configured to control a gain of the amplifier based on the first compensation correction value.

In an embodiment, an electronic device is provided. The electronic device may comprise an antenna configured to generate an output signal having a target frequency; a memory device configured to store a plurality of generalized residuals corresponding to a plurality of frequencies, respectively; and a communication device configured to control the antenna based on the plurality of generalized residuals. The communication device comprises: a memory circuit configured to store a plurality of representative correction values corresponding to a plurality of representative frequencies, respectively; an interpolation circuit configured to generate an interpolation correction value corresponding to the target frequency based on the plurality of representative correction values; a residual compensation circuit configured to read a first generalized residual corresponding to the target frequency from among the plurality of generalized residuals, and to generate a compensation correction value based on the first generalized residual and the interpolation correction value; and a gain control circuit configured to adjust power of the output signal based on the compensation correction value.

In an embodiment, an operating method of a characteristic analysis device for analyzing characteristics of a plurality of frequencies of a communication device controlling an antenna is provided. The operating method may comprise: generating first to p-th ideal correction value tables based on first to p-th sample communication devices configured to correspond to the communication device, respectively; identifying first to p-th plurality of feature frequencies based on the first to p-th ideal correction value tables, respectively; determining first to n-th representative frequencies based on the first to p-th plurality of feature frequencies; generating first to p-th interpolation correction value tables based on the first to n-th representative frequencies and the first to p-th ideal correction value tables; generating first to p-th correction value residual tables respectively based on the first to p-th interpolation correction value tables and the first to p-th ideal correction value tables; and determining a plurality of generalized residuals based on the first to p-th correction value residual tables, wherein each of n and p is an integer greater than or equal to 2.

### BRIEF DESCRIPTION OF THE DRAWINGS

FIG. 1 is a block diagram showing a communication system according to an example embodiment of the present disclosure.

FIG. 2 is a block diagram illustrating an example configuration of the electronic device of FIG. 1 in more detail.

FIG. 3 is a block diagram illustrating the configuration of the communication device of FIG. 2 in more detail.

FIG. 4 is a block diagram illustrating an example configuration of FIG. 3 in more detail.

FIG. 5 is a diagram illustrating a representative correction value table of FIG. 4 in more detail.

FIG. 6 is a diagram illustrating an example operation of the interpolation circuit of FIG. 4 in more detail.

FIG. 7 is a diagram illustrating an example generalized residual table of FIG. 2 in more detail.

FIG. 8 is a diagram illustrating an example correction value calculation system for calculating a plurality of representative compensation values of FIG. 5.

FIG. 9 is a block diagram illustrating an example communication device characteristic analysis system that determines a plurality of representative frequencies of FIG. 5 and a generalized residual of FIG. 7.

FIGS. 10 to 12 are block diagrams illustrating an example operation of the correction value calculation module of FIG. 9.

FIG. 13 is a diagram illustrating the operation of the feature frequency extraction module of FIG. 9.

FIG. 14 is a graph illustrating an example operation of the representative frequency determination module of FIG. 9 in more detail.

FIGS. 15 and 16 are diagrams illustrating an example operation of the interpolation correction value calculation module of FIG. 9 in more detail.

FIGS. 17 and 18 are diagrams illustrating an example operation of the residual calculation module of FIG. 9 in more detail.

FIGS. 19 and 20 are diagrams illustrating an example operation of the generalized residual calculation module of FIG. 9 in more detail.

FIG. 21 is a diagram showing an error with an ideal correction value when interpolation correction values for a plurality of sample communication devices are compensated based on the generalized residual of FIG. 20.

FIG. 22 is a diagram illustrating an example method of controlling a communication device according to an embodiment of the present disclosure.

FIG. 23 is a diagram illustrating operation S100 of FIG. 22 in more detail.

FIG. 24 is a diagram illustrating operation S200 of FIG. 22 in more detail.

FIG. 25 is a diagram illustrating operation S300 of FIG. 22 in more detail.

FIG. 26 is a block diagram illustrating the example communication device of FIG. 2 implemented according to an embodiment.

FIG. 27 is a diagram illustrating an example correction value calculation system for generating a representative correction value table of FIG. 26.

### DETAILED DESCRIPTION OF THE EMBODIMENTS

Hereinafter, embodiments of the present disclosure will be described clearly and in detail so that those people skilled in the art may easily carry out the present disclosure. Details such as detailed configurations and structures are provided simply to aid in the overall understanding of embodiments of the present disclosure. Therefore, variations of the embodiments described herein without departing from the technical spirit and scope of the present disclosure may be performed by one of ordinary skill in the art. Moreover, descriptions of well-known functions and structures are omitted for clarity and brevity. The components in the following drawings or detailed descriptions may be connected to others other than the components shown in the drawings or described in the detailed description. The terms used in the text are terms defined in consideration of the functions of the present disclosure and are not limited to specific functions. The definition of terms may be determined based on the matters described in the detailed description. Like reference characters refer to like elements throughout.

The components described with reference to terms such as a driver or block used in the detailed description may be implemented in the form of software, hardware, or a combination thereof. For example, the software may be machine code, firmware, embedded code, and application software. For example, hardware may include an electrical circuit, an electronic circuit, a processor, a computer, an integrated circuit core, a pressure sensor, an inertial sensor, MEMS (Micro Electro Mechanical System), a passive device, or a combination thereof.

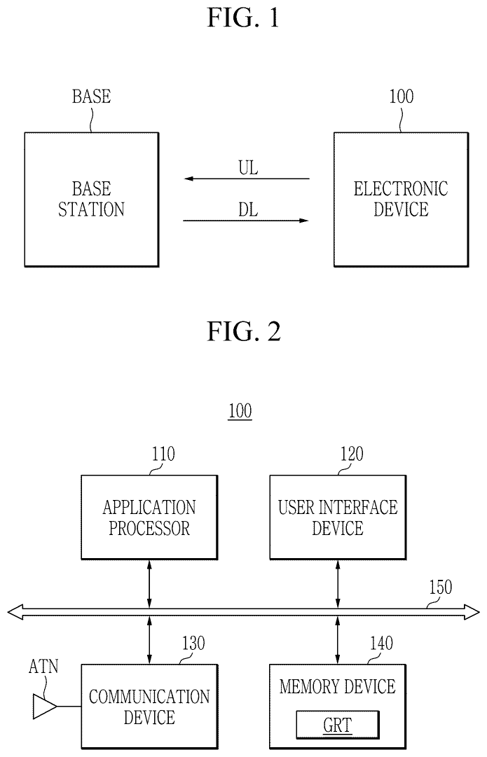

FIG. 1 is a block diagram showing a communication system according to an example embodiment of the present disclosure. Referring to FIG. 1, a communication system may include a base station BASE and an electronic device 100.

A base station BASE may refer to a fixed station that communicates with any type of user equipment and/or other base station. A base station BASE may exchange data with other user equipment and/or other base stations by communicating thereto. For example, a base station BASE may be any type of communication device configured to transmit and/or receive data and/or communications to and/or from one or more electronic devices 100 in wireless communication system, many of which are known in the art. In some embodiments, a base station BASE may also be referred to as, for example, a base transceiver station (BTS), an access point, evolved Node B (ENB), GNodeB, etc.

The electronic device 100 may be any type of wireless communication device exchanging data by communicating with a base station (e.g., base station BASE). For example, the electronic device 100 may be any type of wireless communication device such as a smartphone, a laptop, a navigation, a tablet PC, etc.

The base station BASE and the electronic device 100 may wirelessly communicate with each other. For example, the base station BASE and the electronic device 100 may communicate with each other based on various types of wireless communication protocols such as 5G (5th generation wireless), LTE (Long Term Evolution), etc. However, the scope of the present disclosure is not limited thereto. For example, the base station BASE and the electronic device 100 may communicate with each other based on any type of wireless communication protocol, such as CDMA (Code Division Multiple Access), GSM (Global System for Mobile Communications), WPAN (Wireless Personal Area Network), etc.

The electronic device 100 may transmit data to the base station BASE through an uplink UL, and the electronic device 100 may receive data from the base station BASE through a downlink DL. The transmission loss of the uplink UL and the downlink DL may vary depending on the frequency used for communication between the base station BASE and the electronic device 100.

Meanwhile, the power consumption of the electronic device 100 may vary according to the power of the signal transmitted by the electronic device 100 through the uplink UL. For example, as the power of the signal transmitted by the electronic device 100 through the uplink UL increases, the power consumption of the electronic device 100 may increase. On the other hand, as the power of the signal transmitted by the electronic device 100 through the uplink UL decreases, the power consumption of the electronic device 100 may decrease.

The electronic device 100 may appropriately adjust the power of a signal to be transmitted through the uplink UL by considering power consumption and transmission loss of the uplink UL. For example, the electronic device 100 may adjust the power level of a signal to be transmitted via the uplink UL low enough so that the electronic device 100 does not consume too much power unnecessarily; and may adjust the power level of a signal to be transmitted via the uplink UL high enough so that communication between the base station BASE and the electronic device 100 does not become interrupted due to transmission loss of the uplink UL.

FIG. 2 is a block diagram illustrating a configuration of the electronic device of FIG. 1 in more detail. Referring to FIGS. 1 and 2, the electronic device 100 may include an application processor 110, a user interface device 120, a communication device 130, a memory device 140, and an antenna ATN. The application processor 110, the user interface device 120, the communication device 130, and the memory device 140 may be connected to each other through a bus 150.

The application processor 110 may control overall operations of the electronic device 100. For example, the application processor 110 may control the operation of a user interface device 120, a communication device 130, and a memory device 140.

A user interface device 120 may support interfacing to a user of an electronic device 100. For example, the user interface device 120 may include one or more of various types of user interfacing devices, such as a screen, a keyboard, a microphone, a speaker, a trackpad, a mouse, and the like.

A communication device 130 may support communication with an external device. For example, a communication device 130 may support wireless communication with a base station BASE. For a more detailed example, the communication device 130 may control the antenna ATN to transmit data via the uplink UL or receive data via the downlink DL.

A memory device 140 may include an operating memory and/or a storage memory of the electronic device 100. For example, the memory device 140 may be a volatile memory device such as a DRAM (dynamic random-access memory) device, or a nonvolatile memory device such as a flash memory device.

The memory device 140 may store various types of data used for the operation of the electronic device 100. For example, the memory device 140 may store a generalized residual table GRT. The generalized residual table GRT may include a plurality of generalized residuals (hereinafter, referred to as generalized residuals GR) corresponding to a plurality of frequencies, respectively. For example, each of the plurality of generalized residuals GR may correspond to one of the plurality of frequencies.

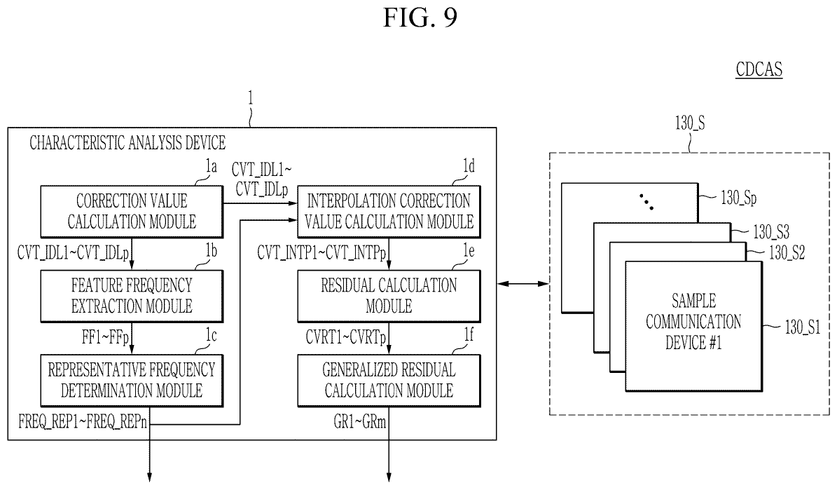

In an embodiment, a plurality of generalized residuals GR may be generated based on a plurality of sample communication devices configured to correspond to the communication device 130. For example, the plurality of generalized residuals GR may be results of statistically analyzing process deviations of the plurality of sample communication devices based on a machine learning algorithm. A method of generating the plurality of generalized residuals will be described in more detail with reference to FIGS. 9 to 20.

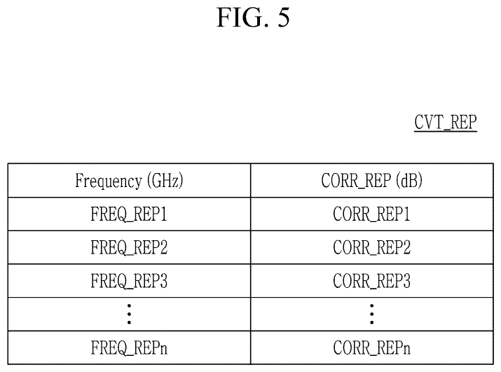

The communication device 130 may determine whether the power level of the signal transmitted by the electronic device 100 through the uplink UL is appropriate. For example, the communication device 130 may measure the power of the signal provided to the antenna ATN. The communication device 130 may read the generalized residual table GRT from memory device 140. The communication device 130 may estimate the power of the signal emitted from the antenna ATN based on the power of the signal provided to the antenna ATN and the generalized residual table GRT. The communication device 130 may determine whether the power level of the signal transmitted through the uplink UL is appropriate based on the magnitude of the power of the signal emitted from the antenna ATN. A method of estimating the power of the signal emitted from the antenna ATN by the communication device 130 will be described in more detail with reference to FIGS. 5 to 7.

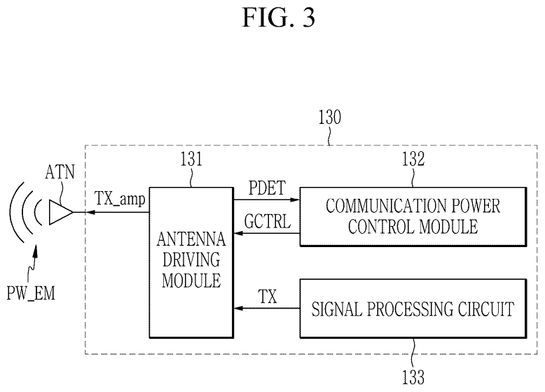

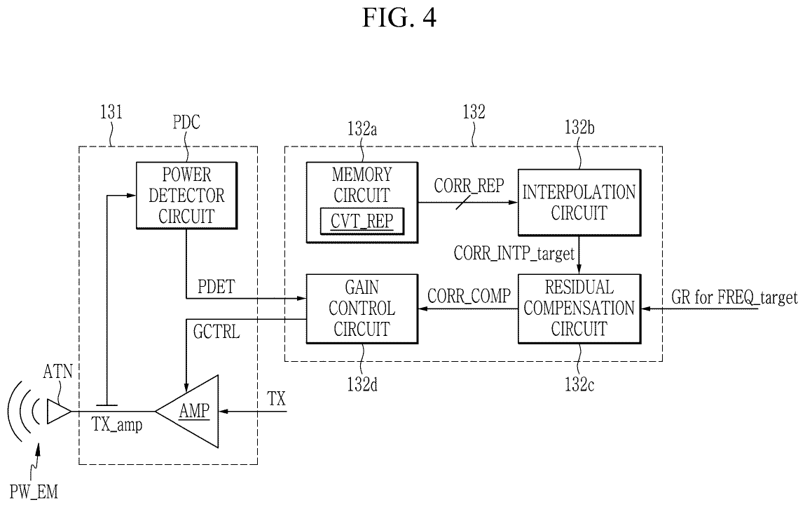

Based on the determination result, the communication device 130 may adjust the power of the signal provided to the antenna ATN. In this case, the power of the signal emitted from the antenna ATN may be adjusted. A method of adjusting the power of the input signal provided to the antenna ATN by the communication device 130 will be described in more detail with reference to FIGS. 3 and 4.

In an embodiment, when the communication device 130 estimates the power of the signal emitted from the antenna ATN based on the generalized residual table GRT, the power of the signal emitted from the antenna ATN may be estimated more accurately. In this case, the communication device 130 may more accurately determine whether the power level of the signal transmitted through the uplink UL is appropriate. Accordingly, according to an embodiment of the present disclosure, the communication device 130 may adjust the power of the input signal provided to the antenna ATN to an optimal power level.

FIG. 3 is a block diagram illustrating the configuration of the communication device of FIG. 2 in more detail. Referring to FIGS. 1 to 3, the communication device 130 may include an antenna driving module 131, a communication power control module 132, and a signal processing circuit 133.

The antenna driving module 131 may drive the antenna ATN. For example, the antenna driving module 131 may set the operation mode of the antenna ATN to the transmission mode or the reception mode. However, hereinafter, for more concise description, an embodiment in which the antenna driving module 131 drives the antenna ATN in the transmission mode will be representatively described.

The antenna driving module 131 may receive an input signal TX from the signal processing circuit 133. The antenna driving module 131 may generate an amplified input signal TX_amp by amplifying the input signal TX. The antenna driving module 131 may provide an amplified input signal TX_amp to the antenna ATN. In this case, the antenna ATN may output a signal corresponding to the amplified input signal TX_amp. Hereinafter, the power of the signal output from the antenna ATN will be referred to as an emission power PW_EM.

The antenna driving module 131 may detect the power of the amplified input signal TX_amp. For example, the antenna driving module 131 may generate a detected power value PDET corresponding to the power level of the amplified input signal TX_amp.

The antenna driving module 131 may provide the detected power value PDET to the communication power control module 132. The communication power control module 132 may estimate the emission power PW_EM based on the detected power value PDET. For example, the communication power control module 132 may estimate the emission power PW_EM based on the detected power value PDET and the generalized residual table GRT.

The communication power control module 132 may control the operation of the antenna driving module 131 based on the estimated emission power PW_EM. For example, the communication power control module 132 may generate a gain control signal GCTRL based on the estimated emission power PW_EM. The communication power control module 132 may provide the gain control signal GCTRL to the antenna driving module 131. In this case, the antenna driving module 131 may adjust the amplification gain used to generate the amplified input signal TX_amp based on the input signal TX in response to the gain control signal GCTRL.

FIG. 4 is a block diagram illustrating some configuration of FIG. 3 in more detail. Referring to FIGS. 1 to 4, the antenna driving module 131 may include an amplifier AMP and a power detection circuit PDC.

The amplifier AMP may receive the input signal TX. The amplifier AMP may generate an amplified input signal TX_amp by amplifying the input signal TX. The amplifier AMP may provide the amplified input signal TX_amp to the antenna ATN.

In an embodiment, the amplifier AMP may be implemented as a variable gain amplifier. For example, the gain of the amplifier AMP may be adjusted in response to a gain control signal GCTRL.

For a more concise explanation, FIG. 4 illustrates that the amplifier AMP directly receives the input signal TX, but the scope of the present disclosure is not limited thereto. For example, the antenna driving module 131 may further include various types of signal modulation circuits, such as a phase shifter, and the amplifier AMP may be configured to receive an input signal TX modulated by these signal modulation circuits.

The power detection circuit PDC may measure the power of the amplified input signal TX_amp. The power detection circuit PDC may generate the detected power value PDET indicating power of the amplified input signal TX_amp.

The communication power control module 132 may estimate the emission power PW_EM based on the detected power value PDET and the generalized residual GR. The communication power control module 132 may control the gain of the amplifier AMP based on the estimated emission power PW_EM. For example, the communication power control module 132 may generate the gain control signal GCTRL based on a frequency (hereinafter, referred to as a target frequency FREQ_target) of the input signal TX.

Hereinafter, a scheme in which the communication power control module 132 generates the gain control signal GCTRL based on the target frequency FREQ_target will be described.

The communication power control module 132 may include a memory circuit 132a, an interpolation circuit 132b, a residual compensation circuit 132c, and a gain control circuit 132d.

The memory circuit 132a may include a representative correction value table CVT_REP. The representative correction value table CVT_REP may include a plurality of representative correction values (hereinafter, referred to as representative correction values FREQ_REP) corresponding to a plurality of representative frequencies (hereinafter, referred to as representative frequencies CORR_REP).

In an embodiment, the memory circuit 132a may be implemented by an OTP (one time programmable) memory circuit.

The interpolation circuit 132b may read a plurality of representative correction values CORR_REP from the memory circuit 132a. An interpolation circuit 132b may generate an interpolation correction value CORR_INTP_target corresponding to a target frequency FREQ_target by interpolating a plurality of representative correction values CORR_REP.

In an embodiment, the interpolation circuit 132b may generate an interpolation correction value CORR_INTP_target by linearly interpolating a plurality of representative correction values CORR_REP. However, the scope of the present disclosure is not limited to the specific algorithm that the interpolation circuit 132b uses to generate the interpolation correction value CORR_INTP_target.

The residual compensation circuit 132c may read the generalized residual GR for the target frequency FREQ_target. For example, the residual compensation circuit 132c may read a generalized residual GR corresponding to the target frequency FREQ_target from a generalized residual table GRT.

The residual compensation circuit 132c may receive the interpolation correction value CORR_INTP_target. The residual compensation circuit 132c may calculate a compensation correction value CORR_COMP based on the generalized residual GR corresponding to a target frequency FREQ_target and the interpolation correction value CORR_INTP_target. For example, the residual compensation circuit 132c may calculate the compensation correction value CORR_COMP by adding the generalized residual GR corresponding to the target frequency FREQ_target with the interpolation correction value CORR_INTP_target.

The gain control circuit 132d may receive the detected power value PDET and the compensation correction value CORR_COMP. The gain control circuit 132d may estimate the emission power PW_EM based on the detected power value PDET and the compensation correction value CORR_COMP. For example, the gain control circuit 132d may estimate the emission power PW_EM by adding the compensation correction value CORR_COMP to the detected power value PDET.

The gain control circuit 132d may generate a gain control signal GCTRL based on the estimated emission power PW_EM. In this case, the gain of the amplifier AMP may be adjusted in response to the gain control signal GCTRL, and accordingly, the power level of the amplified input signal TX_amp may be adjusted. Therefore, according to an embodiment of the present disclosure, based on the amplified input signal TX_amp, the antenna ATN may generate a signal having a power magnitude great enough to transmit data to the base station BASE successfully.

FIG. 5 is a diagram illustrating a representative correction value table of FIG. 4 in more detail. Referring to FIGS. 1 to 5, the memory circuit 132a may include a representative table CVT_REP. The representative correction value table CVT_REP may include a plurality of representative correction values CORR_REP corresponding to a plurality of different representative frequencies FREQ_REP.

For example, the representative correction value table CVT_REP may include first to n-th representative correction values CORR_REP1 to CORR_REPn. The first to n-th representative correction values CORR_REP1 to CORR_REPn may correspond to the first to n-th representative frequencies FREQ_REP1 to FREQ_REPn, respectively. Herein, n may be an integer greater than or equal to 2.

In an embodiment, the frequency intervals of the first to n-th representative frequencies FREQ_REP1 to FREQ_REPn may not be uniform.

In an embodiment, the first to n-th representative correction values CORR_REP1 to CORR_REPn may be calculated at a generation stage of the communication device 130. For example, the first to n-th representative correction values CORR_REP1 to CORR_REPn may be stored in the memory circuit 132a in the generation stage of the communication device 130.

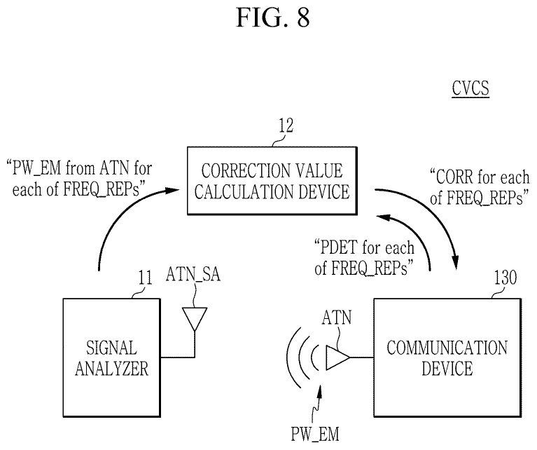

In an embodiment, each of the first to n-th representative correction values CORR_REP1 to CORR_REPn may indicate a difference between the detected power value PDET and the emission power PW_EM when the antenna ATN is driven based on the input signal TX having a corresponding representative frequency. In other words, each of the first to n-th representative correction values CORR_REP1 to CORR_REPn may represent an optimal correction value for a case in which the antenna driving module 131 operates based on the input signal TX having a corresponding representative frequency. A method of calculating the first to n-th representative correction values CORR_REP1 to CORR_REPn will be described in more detail with reference to FIG. 8 below.

In an embodiment, each of the first to n-th representative frequencies FREQ_REP1 to FREQ_REPn may be included in a frequency band used by the communication device 130 for wireless communication. The first to n-th representative frequencies FREQ_REP1 to FREQ_REPn may be determined at a development stage which is preceding the generation stage of the communication device 130. A method in which the first to n-th representative frequencies FREQ_REP1 to FREQ_REPn are determined will be described in more detail with reference to FIGS. 9 to 14.

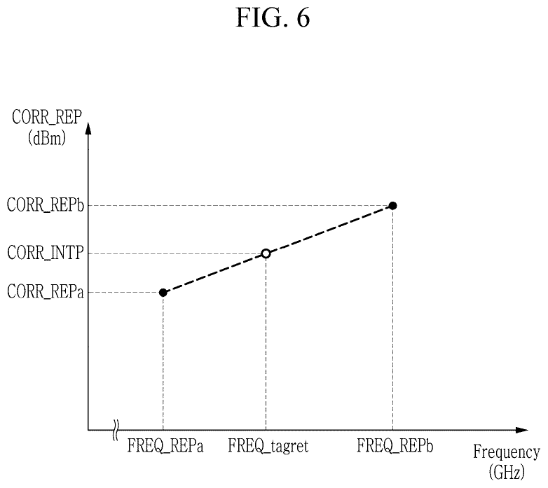

FIG. 6 is a diagram illustrating an example operation of the interpolation circuit of FIG. 4 in more detail. Hereinafter, with reference to FIGS. 1 to 6, an embodiment in which an interpolation circuit 132b generates an interpolation correction value CORR_INTP_target based on a linear interpolation algorithm will be described.

The interpolation circuit 132b may read a plurality of representative correction values CORR_REP included in the representative correction value table CVT_REP from the memory circuit 132a. For example, the interpolation circuit 132b may read representative correction values CORR_REPa and CORR_REPb respectively corresponding to two representative frequencies FREQ_REPa and FREQ_REPb from among the first to n-th representative frequencies FREQ_REP1 to FREQ_REPn, which are adjacent to the target frequency FREQ_target.

In an embodiment, one of the representative frequencies FREQ_REPa and FREQ_REPb may be smaller than the target frequency FREQ_target. The other one of the representative frequencies FREQ_REPa and FREQ_REPb may be greater than or equal to the target frequency FREQ_target. Hereinafter, for more concise description, it is assumed that the representative frequency FREQ_REPa is smaller than the target frequency FREQ_target and the representative frequency FREQ_REPb is larger than the target frequency FREQ_target.

The interpolation circuit 132b may generate an interpolation correction value CORR_INTP_target by interpolating the representative correction values CORR_REPa and CORR_REPb. For example, the interpolation circuit 132b may calculate the interpolation correction value CORR_INTP_target based on Equation 1 below.

$$( Equation 1 )$$

$$CORR\_INTP \_target = CORR\_REPa + \frac{CORR\_REPb - CORR\_REPa}{FREQ\_REPb - FREQ\_REPa} \times ( FREQ\_target - FREQ\_REPa )$$

In this way, even if the target frequency FREQ_target has an arbitrary frequency magnitude, the interpolation circuit 132b may generate an interpolation correction value CORR_INTP_target corresponding to the target frequency FREQ_target.

However, unlike the plurality of representative correction values CORR_REP included in the representative correction value table CVT_REP, the interpolation correction value CORR_INTP_target may not be an optimal correction value for the case where the antenna driving module 131 operates based on the input signal TX having the target frequency FREQ_target. For example, when the interpolation correction value CORR_INTP_target and the antenna driving module 131 operate based on the target frequency FREQ_target, the sum of the detected power value PDET and the interpolation correction value CORR_INTP_target may be different from the emission power PW_EM.

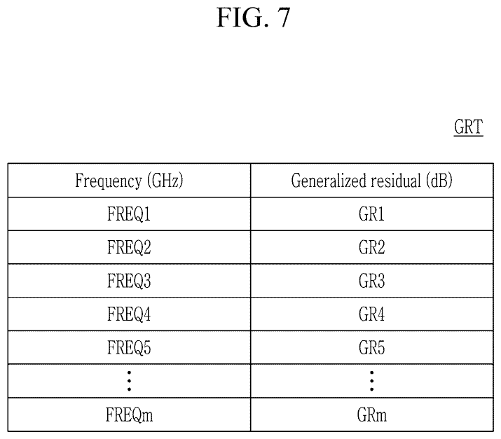

FIG. 7 is a diagram illustrating a generalized residual table of FIG. 2 in more detail. Referring to FIGS. 1 to 7, a generalized residual table GRT may include the plurality of generalized residuals GR corresponding to a plurality of frequencies FREQ different each other. For example, a generalized residual table GRT may include first to m-th generalized residuals GR1 to GRm. The first to m-th generalized residuals GR1 to GRm may correspond to the first to m-th frequencies FREQ1 to FREQm, respectively.

In an embodiment, the frequency intervals of the first to m-th frequencies FREQ1 to FREQm may be uniform. However, the scope of the present disclosure is not limited thereto.

In an embodiment, each of the first to m-th frequencies FREQ1 to FREQm may be included in a frequency band used by the communication device 130 for wireless communication. For example, each of the first to m-th frequencies FREQ1 to FREQm may be frequencies which divide the frequency band into uniform intervals. However, the scope of the present disclosure is not limited thereto.

In an embodiment, an interval between the first to m-th frequencies FREQ1 to FREQm may be smaller than an interval between the first to n-th representative frequencies FREQ_REQ1 to FREQ_REPn. For example, m may be an integer greater than n.

In an embodiment, the first to m-th generalized residuals GR1 to GRm may be calculated at the development stage of the communication device 130. For example, the first to m-th generalized residuals GR1 to GRm may be stored in the memory device 140 during the development stage of the communication device 130.

In an embodiment, the first to m-th generalized residuals GR1 to GRm may be generated based on a plurality of sample communication devices configured to correspond to the communication device 130. For example, the first to m-th generalized residuals GR1 to GRm may be a result of statistically analyzing process deviations of a plurality of sample communication devices through a machine learning algorithm. A method of generating the plurality of generalized residuals will be described in more detail with reference to FIGS. 9 to 20.

The residual compensation circuit 132c may read the generalized residual GR corresponding to the target frequency FREQ_target from among the first to m-th generalized residuals GR1 to GRm. For example, when the target frequency FREQ_target is the third frequency FREQ3, the residual compensation circuit 132c may read the third generalized residual GR3 from the memory device 140. The residual compensation circuit 132c may calculate the compensation correction value CORR_COMP by adding the read generalized residual GR and the interpolation correction value CORR_INTP_target. In this case, the compensation correction value CORR_COMP may be a correction value for statistically compensating production deviation which may occur on production stage of the communication device 130. Therefore, the compensation correction value CORR_COMP may be a value similar to an optimal correction value for the case where the antenna driving module 131 operates based on the input signal TX having the target frequency FREQ_target.

As a result, according to an embodiment of the present disclosure, the communication device 130 may accurately estimate the emission power PW_EM based on the generalized residual GR corresponding to the target frequency FREQ_traget. In this case, since the emission power PW_EM of the antenna ATN may be finely and appropriately adjusted, power consumption of the communication device 130 may be reduced, and communication stability of the communication device 130 may be improved also.

FIG. 8 is a diagram illustrating a correction value calculation system for calculating a plurality of representative compensation values of FIG. 5. Referring to FIGS. 1 to 5 and 8, the correction value calculation system CVCS may include a signal analyzer 11, a correction value calculation device 12, and a communication device 130 described above with reference to FIGS. 1 to 7. The correction value calculation system CVCS may operate in the generation stage of the communication device 130.

A communication device 130 may operate based on an arbitrary representative frequency FREQ_REP. For example, the communication device 130 may drive the antenna ATN based on the first representative frequency FREQ_REP1.

A communication device 130 may measure the power of the amplified input signal TX_amp while driving the antenna ATN based on an arbitrary representative frequency FREQ_REP. For example, while the communication device 130 drives the antenna ATN based on the first representative frequency FREQ_REP1, the power detection circuit PDC may generate a detected power value PDET by detecting the power of the amplified input signal TX_amp. The communication device 130 may provide the detected power value PDET to the correction value calculation device 12.

The signal analyzer 11 may measure the emission power PW_EM from the antenna ATN based on the signal analysis antenna ATN_SA. For example, while the communication device 130 drives the antenna ATN based on the first representative frequency FREQ_REP1, the signal analyzer 11 may measure the emission power PW_EM of the antenna ATN. A signal analyzer 11 may provide the measured emission power PW_EM to the correction value calculation device 12.

The correction value calculation device 12 may calculate the correction value CORR based on the emission power PW_EM and the detected power value PDET. For example, when the communication device 130 drives the antenna ATN based on the first representative frequency FREQ_REP1, the correction value calculation device 12 may calculate the first representative correction value CORR_REP1 by subtracting the detected power value PDET from the emission power PW_EM. Therefore, when the communication device 130 drives the antenna ATN based on the first representative frequency FREQ_REP1, the communication device 130 may accurately estimate the emission power PW_EM based on the first representative correction value CORR_REP and the detected power value PDET.

In this way, the communication device 130 may operate based on each of the first to n-th representative frequencies FREQ_REP1 to FREQ_REPn; the signal analyzer 11 may measure emission powers PW_EM respectively corresponding thereto (which may also be referred to as the first to n-th emission power PW_EM1 to PW_EMn); the communication device 130 may generate detected power values PDET respectively corresponding to the first to n-th representative frequencies FREQ_REP1 to FREQ_REPn (which may also be referred to as the first detected power value PDET1 to PDETN); and the correction value calculation device 12 may calculate the first to n-th representative correction values CORR_REP1 to CORR_REPn.

For example, each of the first to n-th representative correction values CORR_REP1 to CORR_REPn may be an optimal correction value for the case where the communication device 130 operates based on the corresponding representative frequency FREQ_REP. Therefore, when the communication device 130 drives the antenna ATN based on one of the first to n-th representative correction values CORR_REP1 to CORR_REPn, the communication device 130 may be able to accurately estimate the emission power PW_EM based on the first to n-th representative correction values CORR_REP1 to CORR_REPn.

FIG. 9 is a block diagram illustrating an example communication device characteristic analysis system that determines a plurality of representative frequencies of FIG. 5 and the generalized residuals of FIG. 7. Referring to FIGS. 1 to 7 and 9, a communication device characteristic analysis system CDCAS may include a characteristic analysis device 1 and a plurality of sample communication devices 130_S. The communication device characteristic analysis system CDCAS may operate at a development stage before the generation stage of the communication device 130.

The plurality of sample communication devices 130_S may include first to p-th sample communication devices 130_S1 to 130_Sp. Each of the first to p-th sample communication devices 130_S1 to 130_Sp may be configured to correspond to the communication device 130. For example, each of the first to p-th sample communication devices 130_S1 to 130_Sp may have the same configuration as the communication device 130, and may be produced by the same production process. However, the scope of the present disclosure is not limited thereto, and each of the first to p-th sample communication devices 130_S1 to 130_Sp may include an antenna driving module that has the same configuration as the antenna driving module 131 and is produced by the same production process thereof. Herein, p is an integer greater than or equal to 2.

The characteristic analysis device 1 may generate first to n-th representative frequencies FREQ_REP1 to FREQ_REPn and first to m-th generalized residuals GR1 to GRm based on the statistical characteristic of the communication device 130. For example, the characteristic analysis device 1 may generate first to n-th representative frequencies FREQ_REP1 to FREQ_REPn and first to m-th generalized residuals GR1 to GRm based on the first to p-th sample communication devices 130_S1 to 130_Sp. Hereinafter, the configuration and operation of the characteristic analysis device 1 will be described in more detail.

The characteristic analysis device 1 may include a correction value calculation module 1a, a feature frequency extraction module 1b, a representative frequency determination module 1c, an interpolation correction value calculation module 1d, a residual calculation module 1e, and a generalized residual calculation module 1f.

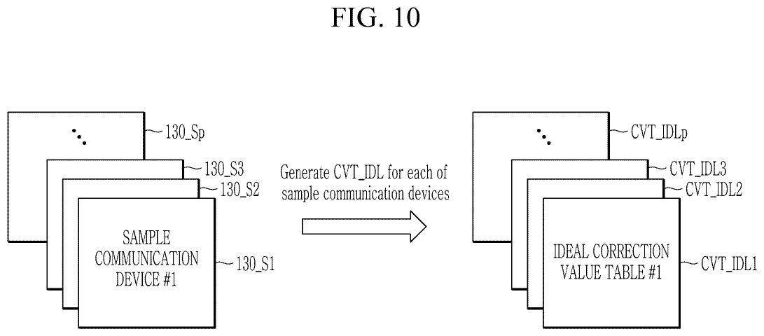

The correction value calculation module 1a may calculate a correction value CORR for each case where each of the first to p-th sample communication devices 130_S1 to 130_Sp operates at the first to m-th frequencies FREQ1 to FREQm, in a similar manner to the correction value calculation device 12 described above with reference to FIG. 8. For example, the correction value calculation module 1a may generate first to p-th ideal correction value tables CVT_IDL1 to CVT_IDLp corresponding to the first to p-th sample communication devices 130_S1 to 130_Sp, respectively. In this case, each of the first to p-th ideal correction value tables CVT_IDL1 to CVT_IDLp may include a plurality of ideal correction values (hereinafter, referred to as ideal correction values CORR_IDL) corresponding to the first to m-th frequencies FREQ1 to FREQm, respectively. The operation of the correction value calculation module 1a will be described in more detail with reference to FIGS. 10 to 12.

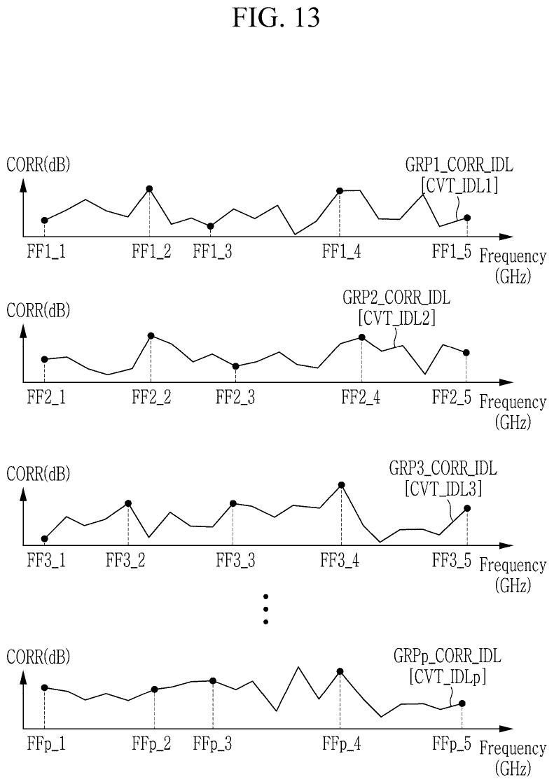

The feature frequency extraction module 1b may extract first to p-th plurality of feature frequencies FF1 to FFp corresponding to the first to p-th sample communication devices 130_S1 to 130_Sp, respectively, based on the first to p-th ideal correction value tables CVT_IDL1 to CVT_IDLp. For example, the feature frequency extraction module 1b may extract a first plurality of feature frequencies FF1 corresponding to the first sample communication device 130_S1 based on the first ideal correction value table CVT_IDL1. The operation of the feature frequency extraction module 1b will be described in more detail with reference to FIG. 13.

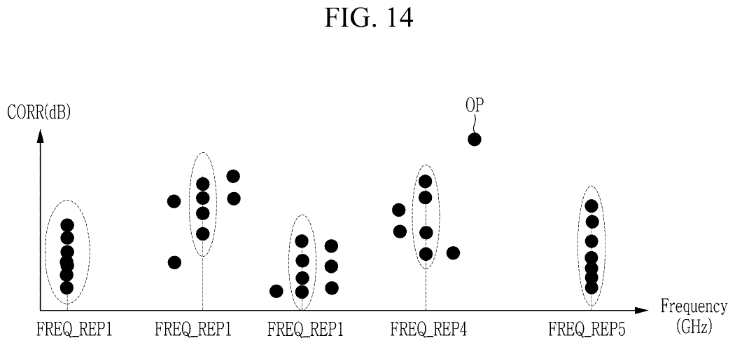

The representative frequency determination module 1c may determine the first to n-th representative frequencies FREQ_REP1 to FREQ_REPn based on the first to p-th plurality of feature frequencies FF1 to FFp. For example, the representative frequency determination module 1c may determine some of the first to p-th plurality of feature frequencies FF1 to FFp as first to n-th representative frequencies FREQ_REP1 to FREQ_REPn. The operation of the representative frequency determination module 1c will be described in more detail with reference to FIG. 14.

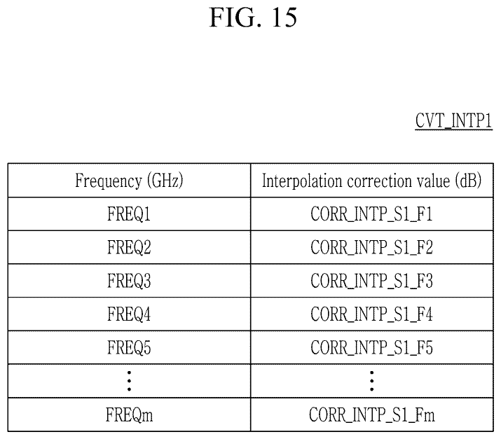

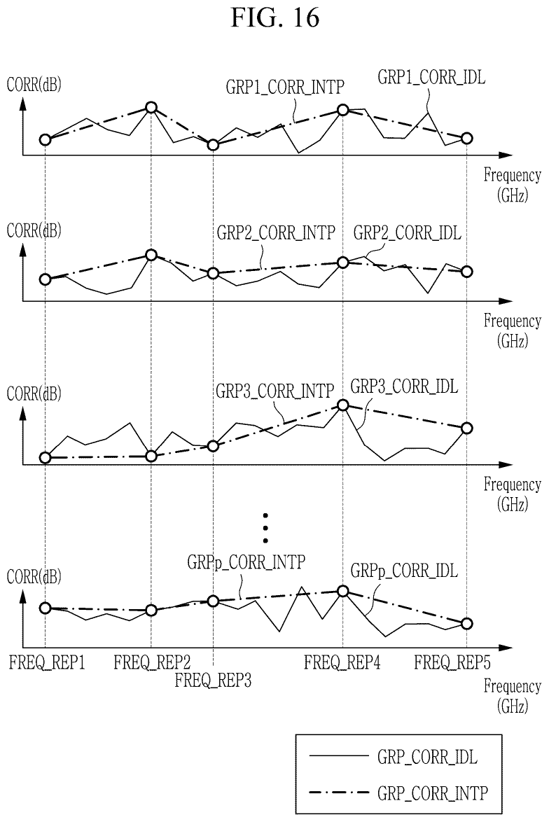

The interpolation correction value calculation module 1d may generate first to p-th interpolation correction value tables CVT_INTP1 to CVT_INTPp based on the first to n-th representative frequencies FREQ_REP1 to FREQ_REPn and the first to p-th ideal correction value tables CVT_IDL1 to CVT_IDLp. For example, the interpolation correction value calculation module 1d may generate the first to p-th interpolation correction value tables CVT_INTP1 to CVT_INTPp, by interpolating ideal correction values CORR_IDL corresponding to the first to n-th representative frequencies FREQ_REP1 to FREQ_REPn included in the first to p-th ideal correction value tables CVT_IDL1 to CVT_IDLp, respectively. An operation of the interpolation correction value calculation module 1d will be described in more detail with reference to FIGS. 15 to 16.

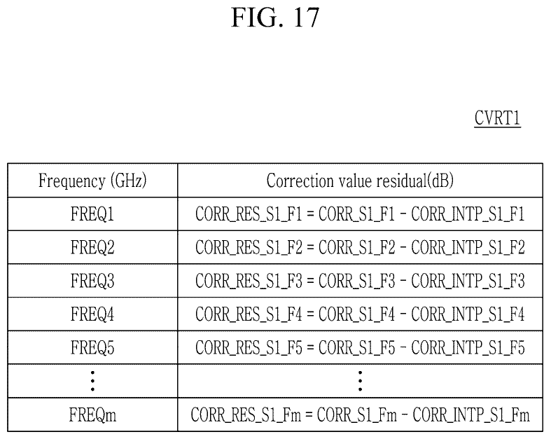

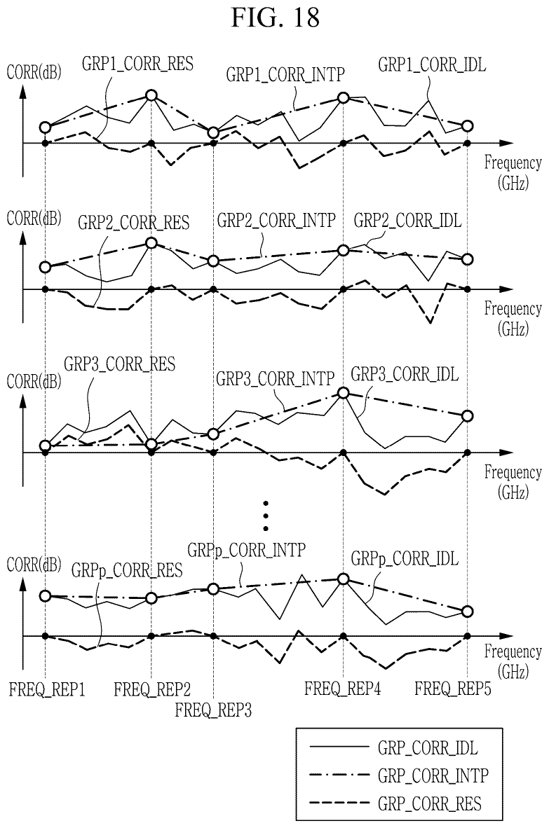

The residual calculation module 1e may generate first to p-th correction value residual tables CVRT1 to CVRTp based on the first to p-th interpolation correction value tables CVT_INTP1 to CVT_INTPp and the first to p-th ideal correction value tables CVT_IDL1 to CVT_IDLp, respectively. For example, the residual calculation module 1e may generate the first to p-th correction value residual tables CVRT1 to CVRTp based on a difference between the first to p-th interpolation correction value tables CVT_INTP1 to CVT_INTPp and the first to p-th ideal correction value tables CVT_IDL1 to CVT_IDLp, respectively. The operation of the residual calculation module 1e will be described in more detail with reference to FIGS. 17 to 18.

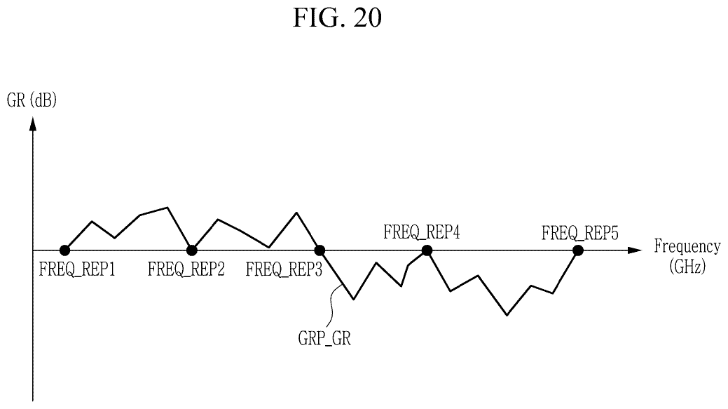

The generalized residual calculation module if may generate first to m-th generalized residuals GR1 to GRm based on the first to p-th correction value residual tables CVRT1 to CVRTp. For example, the generalized residual calculation module 1f may generate generalized residuals GRs for the communication device 130, which are generated by statistically analyzing the plurality of sample communication devices 130_S. An operation of the generalized residual calculation module 1f will be described in more detail with reference to FIG. 20.

FIGS. 10 to 12 are block diagrams illustrating an example operation of the correction value calculation module of FIG. 9.

First, referring to FIGS. 1 to 7 and FIGS. 9 to 10, the correction value calculation module 1a may generate first to p-th ideal correction value tables CVT_IDL1 to CVT_IDLp corresponding to the first to p-th sample communication devices 130_S1 to 130_Sp, respectively. For example, the correction value calculation module 1a may generate the first ideal correction value table CVT_IDL1 based on the first sample communication device 130_S1, and may generate the second ideal correction value table CVT_IDL2 based on the second sample communication device 130_S2.

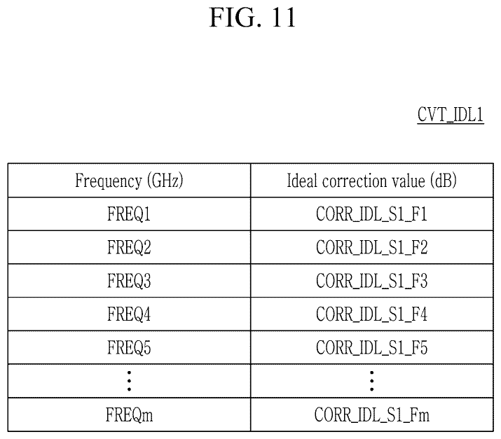

Further referring to FIG. 11, the first ideal correction value table CVT_IDL1 may include a plurality of ideal correction values CORR_IDL_S1_F1 to CORR_IDL_S1_Fm. The plurality of ideal correction values CORR_IDL_S1_F1 to CORR_IDL_S1_Fm may correspond to the first to m-th frequencies FREQ1 to FREQm, respectively. For example, the correction value calculation module 1a may individually calculate optimal correction values for cases in which the first sample communication device 130_S1 operates based on the first to m-th frequencies FREQ1 to FREQm, respectively.

For a more detailed example, in a manner similar to that described with reference to FIG. 8, the correction value calculation module 1a may calculate the ideal correction value CORR_IDL_S1_Fi (wherein ‘i’ is an integer greater than or equal to 1 and less than or equal to ‘m’). In this case, the ideal correction value CORR_IDL_S1_Fi may represent an optimal correction value for estimating the emission power PW_EM for the case where the first sample communication device 130_S1 operates based on the i-th frequency FREQi.

For a more concise explanation, the first ideal correction value table CVT_IDL1 is described as a representative example, but the scope of the present disclosure is not limited thereto, and the second to p-th ideal correction value tables CVT_IDL2 to CVT_IDLp may also be implemented in a similar manner. For example, the k-th ideal correction value table CVT_IDLk (where ‘k’ is an integer greater than or equal to 1 and less than or equal to ‘p’) may include correction values CORR_Sk_F1 to CORR_Sk_Fm.

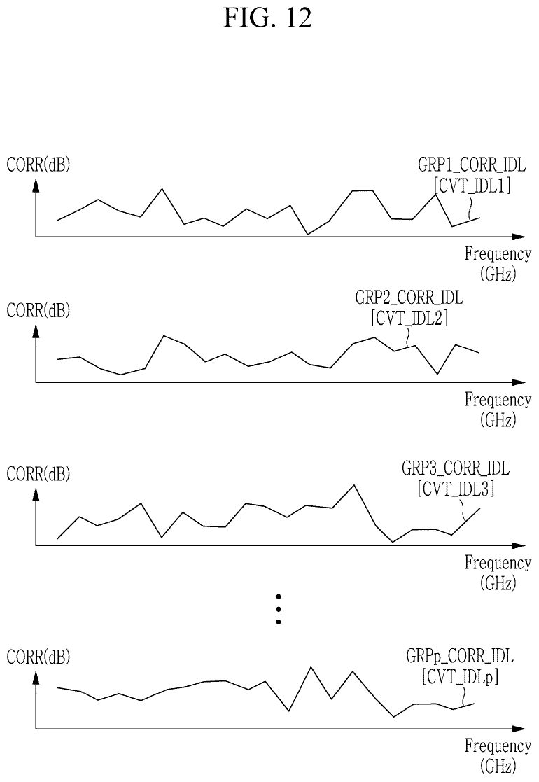

Further referring to FIG. 12, the correction values included in the first to p-th ideal correction value tables CVT_IDL1 to CVT_IDLp may be respectively depicted as the first to p-th ideal correction value graphs GRP1_CORR_IDL to GRPp_CORR_IDL. For example, the correction values included in the first ideal correction value table CVT_IDL1 may be depicted as a first ideal correction value graph GRP1_CORR_IDL.

The horizontal axis of each of the first to p-th ideal correction value graphs GRP1_CORR_IDL to GRPp_CORR_IDL may represent a frequency, and the vertical axis may represent a correction value.

The shapes of the first to p-th ideal correction value graphs GRP1_COR_IDL to GRPp_COR_IDL may be different from each other. In other words, the ideal correction values CORR_IDL included in each of the first to p-th ideal correction value tables CVT_IDL1 to CVT_IDLp may be different from each other. For example, due to a process deviation of the first to p-th sample communication devices 130_S1 to 130_Sp, the ideal correction values CORR_IDL included in each of the first to p-th ideal correction value tables CVT_IDL1 to CVT_IDLp may be different.

FIG. 13 is a diagram illustrating the operation of the feature frequency extraction module of FIG. 9. Referring to FIGS. 1 to 7 and 9 to 13, the feature frequency extraction module 1b may extract the first to p-th plurality of feature frequencies FF1 to FFp based on the first to p-th ideal correction value tables CVT_IDL1 to CVT_IDLp, respectively. For example, the feature frequency extraction module 1b may independently extract a plurality of feature frequencies FFs for the first to p-th ideal correction value tables CVT_IDL1 to CVT_IDLp. For example, the feature frequency extraction module 1b may extract the first plurality of feature frequencies FF1 based on a first ideal correction value table CVT_IDL1, and may extract a second plurality of feature frequencies FF2 based on a second ideal correction value table CVT_IDL2.

In an embodiment, the feature frequency extraction module 1b may extract a plurality of feature frequencies FFs based on various types of machine learning algorithms, such as SVR (support vector regression). For example, the feature frequency extraction module 1b may determine some frequencies as the feature frequency FF, at which the tendency of the ideal correction value CORR_IDL changes (e.g., to increase or decrease) as the frequency FREQ increases. However, the scope of the present disclosure is not limited to a specific algorithm in which the feature frequency extraction module 1b extracts the feature frequencies FFs.

In an embodiment, the feature frequency extraction module 1b may extract the same number of feature frequencies FFs from each of the first to p-th ideal correction value tables CVT_IDL1 to CVT_IDLp. For example, the feature frequency extraction module 1b may extract ‘n’ feature frequencies FFs from each of the first to p-th ideal correction value tables CVT_IDL1 to CVT_IDLp. However, the scope of the present disclosure is not limited thereto, and the same or different number of feature frequencies FF may be extracted from each of the first to p-th ideal correction value tables CVT_IDL1 to CVT_IDLp.

However, for a more concise explanation, an example in which the feature frequency extraction module 1b extracts five feature frequencies FFs from each of the first to p-th ideal correction value tables CVT_IDL1 to CVT_IDLp will be described as a representative example. For example, hereinafter, an example in which ‘n’ is 5 will be described as a representative example. However, the scope of the present disclosure is not limited thereto.

Each of the first to p-th plurality of feature frequencies FF1 to FF5 may include two or more feature frequencies FF. For example, the first plurality of feature frequencies FF1 may include feature frequencies FF1_1 to FF1_5; and the second plurality of feature frequencies FF2_1 to FF2_5 may include feature frequencies FF2_1 to FF2_5.

The first to p-th plurality of feature frequencies FF1 to FFp may be same or deferent each other. For example, the feature frequencies FF1_1 to FF1_5 may be different from the feature frequencies FF2_1 to FF2_5. For a more detailed example, the feature frequency FF1_3 may be different from the feature frequency FF2_3. In other words, the first to p-th plurality of feature frequencies FF1 to FFp may be determined independently of each other.

FIG. 14 is a graph illustrating an operation of the representative frequency determination module of FIG. 9 in more detail. The horizontal axis of FIG. 14 may represent a frequency, and the vertical axis may represent a correction value.

Referring to FIGS. 1 to 7, and 9 to 14, the representative frequency determination module 1c may determine the first to n-th representative frequencies FREQ_REP1 to FREQ_REPn based on the first to p-th plurality of feature frequencies FF1 to FFp. For example, the representative frequency determination module 1c may determine a plurality of representative frequencies FREQ_REP based on the feature frequencies having the most numerous values among the plurality of first to p-th feature frequencies FF1 to FFp.

For a more detailed example, the dots in FIG. 14 show the first to p-th plurality of feature frequencies FF1 to FFp and the correction values CORR corresponding thereto. In this case, the representative frequency determination module 1c may determine the feature frequency FF corresponding to the most numerous dots as the representative frequency FREQ_REP. For example, the representative frequency determination module 1c may determine the top ‘n’ (e.g., 5) feature frequencies FFs corresponding to the most numerous dots as the first to n-th representative frequencies FREQ_REP1 to FREQ_REPn, respectively. However, the scope of the present disclosure is not limited to the number of frequencies determined by the representative frequency determination module 1c as the representative frequency FREQ_REP.

For a more concise explanation, an embodiment in which the representative frequency determination module 1c determines a plurality of representative frequencies FREQ_REP based on the number of each frequency of the first to p-th plurality of feature frequencies FF1 to FFp has been described, but the scope of the present disclosure is not limited thereto. For example, the representative frequency determination module 1c may determine a feature frequency FF corresponding to an outlier point OP having the smallest correlation among the dots shown in FIG. 14 as the representative frequency FREQ_REP.

FIGS. 15 and 16 are diagrams illustrating an example operation of the interpolation correction value calculation module of FIG. 9 in more detail.

First, referring to FIGS. 1 to 7 and FIGS. 9 to 15, the interpolation correction value calculation module 1d may generate the first to p-th interpolation correction value tables CVT_INTP1 to CVT_INTPp based on the first to n-th representative frequencies FREQ_REP1 to FREQ_REPn and the first to p-th ideal correction value tables CVT_IDL1 to CVT_IDLp. For example, the interpolation correction value calculation module 1d may generate the first to p-th interpolation correction value tables CVT_INTP1 to CVT_INTPp by interpolating the ideal correction values CORR_IDL corresponding to the first to n-th representative frequencies FREQ_REP1 to FREQ_REPn included in each of the first to p-th ideal correction value tables CVT_IDL1 to CVT_IDLp, respectively.

For a more detailed example, the interpolation correction value calculation module 1d may generate a plurality of interpolation correction values CORR_INTP_S1_F1 to CORR_INTP_S1_Fm respectively corresponding to the first to m-th frequencies FREQ1 to FREQm, by interpolating the ideal correction values CORR_IDL corresponding to the first to n-th representative frequencies FREQ_REP1 to FREQ_REPn among the ideal correction values CORR_IDL included in the first interpolation correction value table CVT_INTP1, respectively.

For more concise description, the first interpolation correction value table CVT_INTP1 is representatively illustrated in FIG. 15, but the scope of the present disclosure is not limited thereto, and the second to p-th interpolation correction value tables CVT_INTP2 to CVT_INTPp may also be implemented in a similar manner. For example, the k-th interpolation correction value table CVT_INTPk may include a plurality of interpolation correction values CORR_INTP_Sk_F1 to CORR_INTP_Sk_Fm.

Subsequently, referring further to FIG. 16, the interpolation correction values CORR_INTP included in the first to p-th interpolation correction value tables CVT_INTP1 to CVT_INTPp may be illustrated as first to p-th interpolation correction value graphs GRP1_CORR_INTP to GRPp_CORR_INTP, respectively. For example, the interpolation correction values CORR_INTP included in the first interpolation correction value table CVT_INTP1 may be illustrated as the first interpolation correction value graph GRP1_CORR_INTP. The horizontal axis of the graphs shown in FIG. 16 may represent a frequency, and the vertical axis may represent a correction value.

Referring to the first interpolation correction value graph GRP1_CORR_INTP, when the first sample communication device 130_S1 operates based on an arbitrary frequency other than the first to n-th representative frequencies FRQ_REP1 to FRQ_REPn, large error may occur between the interpolation correction value CORR_INTP and the ideal correction value CORR_IDL. Similarly, referring to the first to p-th interpolation correction value graphs GRP1_CORR_INTP to GRPp_CORR_INTP, when the communication device 130 operates at any frequency other than the first to n-th representative frequencies FREQ_REP1 to FREQ_REPn based on the interpolation correction value CORR_INTP, it may be difficult to accurately estimate the emission power PW_EM from the antenna ATN.

FIGS. 17 and 18 are diagrams illustrating an operation of the residual calculation module of FIG. 9 in more detail. Referring to FIGS. 1 to 7 and 9 to 17, the residual calculation module 1e may generate first to p-th correction value residual tables CVRT1 to CVRTp based on the first to p-th interpolation correction value tables CVT_INTP1 to CVT_INTPp and the first to p-th ideal correction value tables CVT_IDL1 to CVT_IDLp, respectively. For example, the residual calculation module 1e may generate the first to p-th correction value residual tables CVRT1 to CVRTp based on the differences in the first to p-th interpolation correction value tables CVT_INTP1 to CVT_INTPp and the first to p-th ideal correction value tables CVT_IDL1 to CVT_IDLp, respectively.

More specifically, the residual calculation module 1e may calculate the correction value residuals CORR_RES_S1_F1 to CORR_RES_S1_Fm included in the first correction value residual table CVRT1 based on the differences between the ideal correction values included in the first ideal correction value table CVT_IDL1 (i.e., the ideal correction values CORR_IDL_S1_F1 to CORR_IDL_S1_Fm) and the interpolation correction values included in the first interpolation correction value table CVT_INTP1 (i.e., the interpolation correction values CORR_INTP_S1_F1 to CORR_INTP_S1_Fm). In this case, the interpolation correction values CORR_INTP_S1_F1 to CORR_INTP_S1_Fm may correspond to the first to m-th frequencies FREQ1 to FREQm, respectively.

In this way, the residual calculation module 1e may calculate the first to p-th correction value residual tables CVRT1 to CVRTp.

Continuing further with reference to FIG. 18, the correction value residuals CORR_RES included in the first to p-th correction value residual tables CVRT1 to CVRTp may be respectively depicted as first to p-th interpolation correction value graphs GRP1_CORR_RES to GRPp_CORR_RES. For example, the correction value residuals CORR_RES_S1_F1 to CORR_RES_S1_Fm included in the first correction value residual table CVRT1 may be depicted as a first correction value residual graph GRP1_CORR_RES. The horizontal axis of the graphs shown in FIG. 18 may represent a frequency, and the vertical axis may represent a correction value.

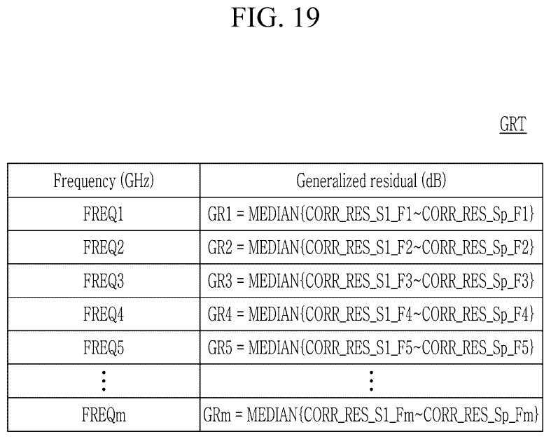

FIGS. 19 and 20 are diagrams illustrating an example operation of the generalized residual calculation module of FIG. 9 in more detail.

First, referring to FIGS. 1 to 7 and FIGS. 9 to 19, the generalized residual calculation module if may generate first to m-th generalized residuals GR1 to GRm corresponding to first to m-th frequencies FREQ1 to FREQm, based on first to p-th correction value residual tables CVRT1 to CVRTp, respectively.

More specifically, the generalized residual calculation module 1f may generate a first generalized residual GR1 based on the correction value residuals (e.g., correction value residuals CORR_RES_S1_F1 to CORR_RES_Sp_F1) corresponding to the first frequency FREQ1 included in each of the first to p-th correction value residual tables CVRT1 to CVRTp. For example, the generalized residual calculation module 1f may determine the median value of the correction value residuals CORR_RES_S1_F1 to CORR_RES_Sp_F1 as the first generalized residual GR1. Likewise, the generalized residual calculation module if may determine the median value of the correction value residuals CORR_RES_S1_F2 to CORR_RES_Sp_F2 as the second generalized residual GR2, determine the median value of the correction value residuals CORR_RES_S1_F3 to CORR_RES_Sp_F3 as the third generalized residual GR3, and so on. However, the scope of the present disclosure is not limited to the specific algorithm used by the generalized residual calculation module if to generate the first generalized residual GR1. For example, the generalized residual calculation module 1f may determine the average value of the correction value residuals CORR_RES_S1_F1 to CORR_RES_Sp_F1 as the first generalized residual GR1.

In this way, the generalized residual calculation module 1f may generate first to m-th generalized residuals GR1 to GRm. In this case, each of the first to m-th generalized residuals GR1 to GRm may reflect correction value residuals (e.g., errors between the ideal correction value CORR_IDL and the interpolation correction value CORR_INTP) of the first to p-th sample communication devices 130_S1 to 130_Sp, that may occur when the interpolation correction values are generated based on the first to n-th representative frequencies FRQ_REP1 to FRQ_REPn. In other words, each of the first to m-th generalized residuals GR1 to GRm may reflect characteristic of the communication device 130 statistically analyzed based on the plurality of sample communication devices 130_S.

Subsequently, referring further to FIG. 20, the median value of each frequency of the correction value residuals CORR_RES included in the first to p-th correction value residual tables CRT1 to CRTp may be illustrated as a generalized residual graph GRP_GR.

In an embodiment, the magnitude of the generalized residual GR corresponding to the first to n-th representative frequencies FREQ_REP1 to FREQ_REPn among the first to m-th generalized residuals GR1 to GRm may be ‘0 dB’.

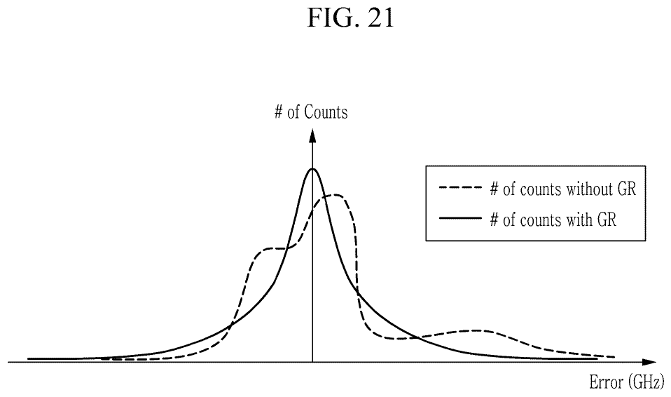

FIG. 21 is a diagram showing an error with an ideal correction value when interpolation correction values for a plurality of sample communication devices are compensated based on the generalized residual of FIG. 20. The horizontal axis of FIG. 21 may indicate an error with an ideal correction value, and the vertical axis may indicate a count.

Referring to FIGS. 1 to 21, as indicated by a dotted line, a difference between the interpolation correction value CORR_INTP and the ideal correction value CORR_IDL may not form a normal distribution. Therefore, when the interpolation correction value CORR_INTP is not compensated based on the first to m-th generalized residuals GR1 to GRm, a difference between the interpolation correction value CORR_INTP and the ideal correction value CORR_IDL may be irregular.

On the other hand, when the interpolation correction value CORR_INTP is compensated based on the first to m-th generalized residuals GR1 to GRm, the difference between the compensated interpolation correction value (i.e., the compensation correction value CORR_COMP) and the ideal correction value CORR_IDL may form a normal distribution. In this case, when an arbitrary compensation correction value CORR_COMP for the communication device 130 is generated based on the generalized residual table GRT, the magnitude of the error between the compensation correction value CORR_COMP and the ideal correction value CORR_IDL may be predicted to be close to ‘0’. Therefore, according to an embodiment of the present disclosure, the interpolation correction value CORR_INTP may be appropriately compensated based on the size of the target frequency FREQ_target, so that the emission power from the antenna ATN may be predicted more accurately.

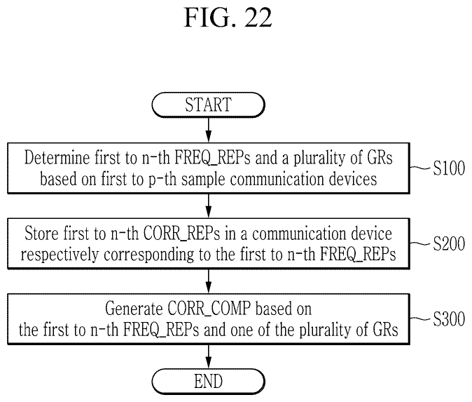

FIG. 22 is a diagram illustrating a method of controlling a communication device according to an example embodiment of the present disclosure. Referring to FIGS. 1 to 22, at operation S100, the characteristic analysis device 1 may determine first to n-th representative frequencies FREQ_REP1 to FREQ_REPn and a plurality of generalized residuals GR based on the first to p-th sample communication devices 130_S1 to 130_Sp. For example, in the development stage of a communication device 130, the characteristic analysis device 1 may determine the first to n-th representative frequencies FREQ_REP1 to FREQ_REPn and the first to m-th generalized residuals GR.

At operation S200, the correction value calculation device 12 may store first to n-th representative correction values CORR_REP1 to CORR_REPn corresponding to first to n-th representative frequencies FREQ_REP1 to FREQ_REPn in the communication device 130. For example, in the generation stage of the communication device 130, the correction value calculation device 12 may store the first to n-th representative correction values CORR_REP1 to CORR_REPn for the communication device 130 in the memory circuit 132a.

In operation S300, the communication device 130 may generate a compensation correction value CORR_COMP based on one of a plurality of generalized residuals GR and the first to n-th representative correction values CORR_REP1 to CORR_REPn. For example, in the use stage of the communication device 130, the communication power control module 132 may generate a compensation correction value CORR_COMP based on the generalized residual, which is one of the first to m-th generalized residuals GRs, corresponding to the operating frequency of the communication device 130. In this case, the communication power control module 132 may appropriately control the gain of the amplifier AMP based on the compensation correction value CORR_COMP.

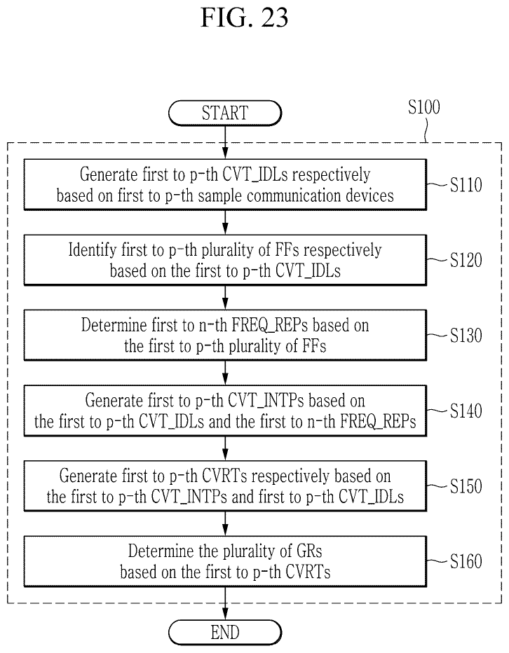

FIG. 23 is a diagram illustrating operation S100 of FIG. 22 in more detail. Referring to FIGS. 1 to 23, operations S100 may include the following operations S110 to S160.

In operation S110, the characteristic analysis device 1 may generate the first to p-th ideal correction value tables CVT_IDL1 to CVT_IDLp based on the first to p-th sample communication devices 130_S1 to 130_Sp, respectively. For example, the correction value calculation module 1a may generate a first ideal correction value table CVT_IDL1 based on the first sample communication device 130_S1, and may generate a second ideal correction value table CVT_IDL2 based on the second sample communication device 130_S2. In this case, each of the first to p-th ideal correction value tables CVT_IDL1 to CVT_IDLp may include a plurality of correction values corresponding to the first to m-th frequencies FREQ1 to FREQm.

In operation S120, the characteristic analysis device 1 may identify first to p-th plurality of feature frequencies FF1 to FFp based on the first to p-th ideal correction value tables CVT_IDL1 to CVT_IDLp. For example, the feature frequency extraction module 1b may extract a first plurality of feature frequencies FF1 based on a first ideal correction value table CVT_IDL1, and may extract a second plurality of feature frequencies FF2 based on a second ideal correction value table CVT_IDL2.

In operation S130, the characteristic analysis device 1 may determine the first to n-th representative frequencies FREQ_REP1 to FREQ_REPn based on the first to p-th plurality of feature frequencies FF1 to FFp. For example, the representative frequency determination module 1c may determine the most numerous frequencies among the first to p-th plurality of feature frequencies FF1 to FFp as the feature frequencies FF as the first to n-th representative frequencies FREQ_REP1 to FREQ_REPn.

In operation S140, the characteristic analysis device 1 may generate first to p-th interpolation correction value tables CVT_INTP1 to CVT_INTPp based on the first to n-th representative frequencies FREQ_REP1 to FREQ_REPn and the first to p-th ideal correction value tables CVT_IDL1 to CVT_IDLp. For example, the interpolation correction value calculation module 1d may generate the first to p-th interpolation correction value tables CVT_INTP1 to CVT_INTPp by interpolating ideal correction values corresponding to the first to n-th representative frequencies FREQ_REP1 to FREQ_REPn included in the first to p-th ideal correction value tables CVT_IDLp, respectively.

In operation S150, the characteristic analysis device 1 may generate the first to p-th correction value residual tables CVRT1 to CVRTp based on the first to p-th ideal correction value tables CVT_IDL1 to CVT_IDLp and the first to p-th interpolation correction value tables CVT_INTP1 to CVT_INTPp, respectively. For example, the residual calculation module 1e may generate the first to p-th correction value residual tables CVRT1 to CVRTp based on a difference between the first to p-th interpolation correction value tables CVT_INTP1 to CVT_INTPp and the first to p-th ideal correction value tables CVT_IDL1 to CVT_IDLp.

In operation S160, the characteristic analysis device 1 may determine a plurality of generalized residuals GRs based on the first to p-th correction value residual tables CVRT1 to CVRTp. For example, the generalized residual calculation module 1f may generate first to m-th generalized residuals GR1 to GRm corresponding to the first to m-th frequencies FREQ1 to FREQm, respectively, based on the first to p-th correction value residual tables CVRT1 to CVRTp.

In an embodiment, the first to m-th generalized residuals GR1 to GRm may be stored in the memory device 140 through a software driver or the like of the communication device 130. However, the scope of the present disclosure is not limited to a specific method in which the first to m-th generalized residuals GR1 to GRm are stored in the memory device 140. In addition, for a more concise explanation, the present disclosure exemplifies an embodiment in which the first to m-th generalized residuals GR1 to GRm are stored in the memory device 140 outside the communication device 130, but the scope of the present disclosure is not limited thereto. For example, the first to m-th generalized residuals GR1 to GRm may be stored in a dedicated memory circuit within the communication device 130. In this case, the first to m-th generalized residuals GR1 to GRm will be stored in a dedicated memory circuit during the generation stage of the communication device 130.

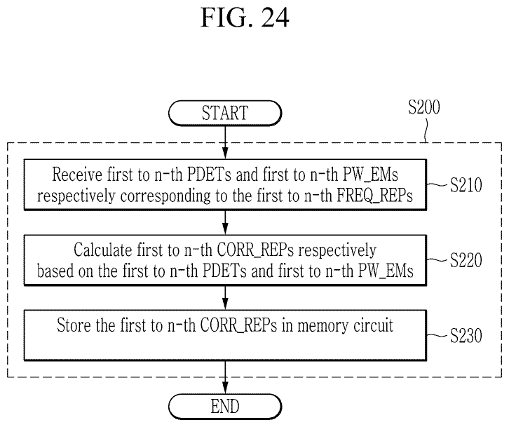

FIG. 24 is a diagram illustrating operation S200 of FIG. 22 in more detail. Referring to FIGS. 1 to 5, 8, and 22 to 24, the operation S200 may include the following operations S210 to S230.

In operation S210, the correction value calculation device 12 may receive first to n-th detected power values PDET1 to PDETn and first to n-th emission powers PW_EM1 to PW_EMn corresponding to the first to n-th representative frequencies FREQ_REP1 to FREQ_REPn, respectively. For example, when the communication device 130 drives the antenna ATN based on the first representative frequency FREQ_REP1, the correction value calculation device 12 may receive the first detected power value PDET1 from the communication device 130 and the first emission power PW_EM1 from the signal analyzer 11. In this way, the correction value calculation device 12 may sequentially receive the first to n-th detected power values PDET1 to PDETn and the first to n-th emission powers PW_EM1 to PW_EMn.

In operation S220, the correction value calculation device 12 may calculate the first to n-th representative correction values CORR_REP1 to CORR_REPn based on the first to n-th detected power values PDET1 to PDETn and the first to n-th emission powers PW_EM1 to PW_EMn, respectively. For example, the correction value calculation device 12 may calculate the first representative correction value CORR_REP1 based on the difference between the first emission power PW_EM1 and the first detected power value PDET1. In this way, the correction value calculation device 12 may sequentially calculate the first to n-th representative correction values CORR_REP1 to CORR_REPn.

For more concise description, an embodiment in which operation S220 is performed after operation S210 is performed is illustrated in FIG. 24, but the scope of the present disclosure is not limited thereto. For example, operations S210 and S220 may be performed simultaneously. For a more detailed example, the correction value calculation device 12 may be configured to calculate a first representative correction value CORR_REP1 in response to receiving a first detected power value PDET1 and a first emission power PW_EM1, and may be configured to calculate a second representative correction value CORR_REP2 in response to receiving a second detected power value PDET2 and a second emission power PW_EM2. For example, the correction value calculation device 12 may be configured to calculate a representative correction value CORR_REP whenever a pair of corresponding emission power PW_EM and detected power value PDET is received.

At operation S230, the correction value calculation device 12 may store the first to n-th representative correction values CORR_REP1 to CORR_REPn in the memory circuit 132a. For example, the correction value calculation device 12 may store a representative correction value table CVT_REP in the memory circuit 132a.

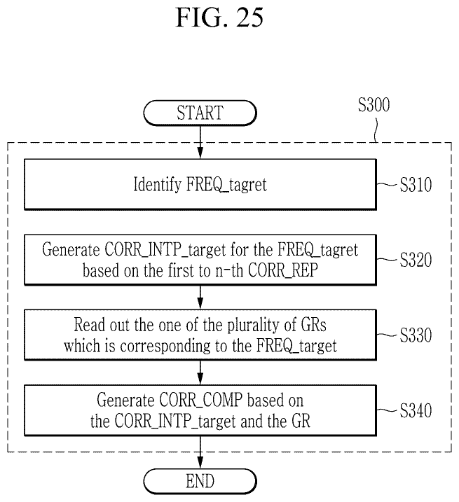

FIG. 25 is a diagram illustrating operation S300 of FIG. 22 in more detail. Referring to FIGS. 1 to 7, and 22 to 25, operation S300 may include the following operations S310 to S340.

In operation S310, the communication device 130 may identify the target frequency FREQ_target. For example, the communication device 130 may identify a frequency of the signal to be transmitted through the antenna ATN.

In operation S320, the communication device 130 may generate an interpolation correction value CORR_INTP_target for the target frequency FREQ_target based on the first to n-th representative correction values CORR_REP1 to CORR_REPn. For example, the interpolation circuit 132b may read two representative correction values CORR_REPa and CORR_REPb included in the representative correction value table CVT_REP from the memory circuit 132a. The interpolation circuit 132b may generate an interpolation correction value CORR_INTP_target for the target frequency FREQ_target by performing linear interpolation for the representative correction values CORR_REPa and CORR_REPb.

At operation S330, the communication device 130 may read out one generalized residual GR corresponding to the target frequency FREQ_target among a plurality of generalized residuals GRs. For example, the residual compensation circuit 132c may read the generalized residual GR corresponding to the target frequency FREQ_target from the generalized residual table GRT stored in the memory device 140.

In operation S340, a communication device 130 may generate the compensation correction value CORR_COMP based on the interpolation correction value CORR_INTP_target and the generalized residual GR for the target frequency FREQ_target. For example, the residual compensation circuit 132c may calculate the compensation correction value CORR_COMP by adding the generalized residual GR and the interpolation correction value CORR_INTP_target.

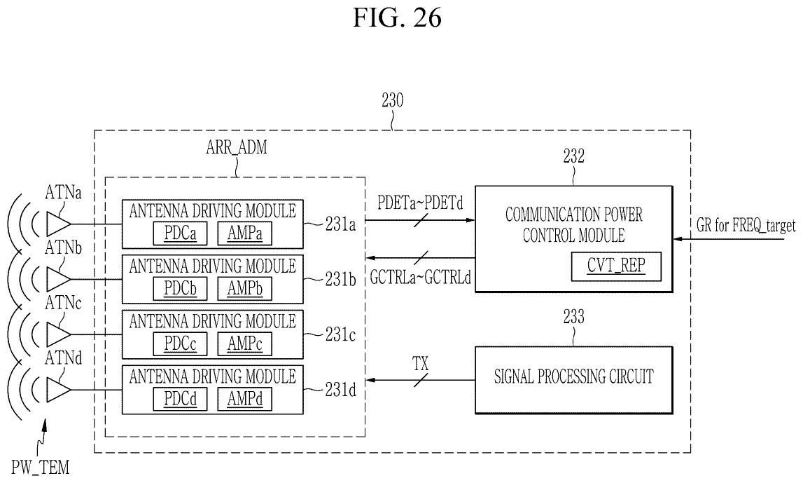

FIG. 26 is a block diagram illustrating the communication device of FIG. 2 implemented according to an example embodiment. Referring to FIGS. 1 to 4 and 26, the communication device 130 may be implemented as the following communication device 230.

The communication device 230 may control a plurality of antennas ATN. For more concise description, hereinafter, an embodiment in which the communication device 230 controls four antennas will be representatively described. For example, the communication device 230 may control the first to fourth antennas ATNa to ATNd.

In an embodiment, a plurality of antennas ATN may form an antenna array.

The communication device 230 may include an antenna driving module array ARR_ADM. The antenna driving module array ARR_ADM may include first to fourth antenna driving modules 231a to 231d. The first to fourth antenna driving modules 231a to 231d may control the first to fourth antennas ATNa to ATNd, respectively. The configuration and operation of the first to fourth antenna driving modules 231a to 231d are substantially the same as the configuration and operation of the antenna driving module 131 described above with reference to FIG. 4, so a detailed description will be omitted.

The first to fourth antenna driving modules 231a to 231d may each include first to fourth amplifiers AMPa to AMPd. Each of the first to fourth amplifiers AMPa to AMPd may amplify the input signal TX received from the signal processing circuit 233. For example, the first to fourth amplifiers AMPa to AMPd may generate an amplified input signal TX_amp similar to that described with reference to FIG. 4. The configuration and operation of the signal processing circuit 233 may be substantially the same as the configuration and operation of the signal processing circuit 133 described above with reference to FIG. 4, so a detailed description will be omitted.

In an embodiment, the input signals TX provided to the first to fourth antenna driving modules 231a to 231d may be the same. However, the scope of the present disclosure is not limited thereto.

In an embodiment, the first to fourth antenna driving modules 231a to 231d may operate simultaneously. For example, the first to fourth antenna driving modules 231a to 231d may simultaneously drive the first to fourth antennas ATNa to ATNd.

The first to fourth antenna driving modules 231a to 231d may include first to fourth power detection circuits PDCa to PDCd, respectively. The first to fourth power detection circuits PDCa to PDCd may detect the power level of the amplified input signal TX_amp generated from the first to fourth amplifiers AMPa to AMPd, respectively. For example, the first to fourth power detection circuits PDCa to PDCd may generate first to fourth detected power values PDETa to PDETd, respectively.

The communication power control module 232 may include a representative correction value table CVT_REP. The representative correction value table CVT_REP may include a plurality of representative correction values CORR_REP corresponding to a plurality of representative frequencies FREQ_REP, respectively.

The communication power control module 232 may receive the generalized residual GR corresponding to the target frequency FREQ_target. The communication power control module 232 may generate the compensation correction value CORR_COMP based on the generalized residual GR and a plurality of representative correction values CORR_REP.

The configuration and operation of the communication power control module 232 are substantially the same as the configuration and operation of the communication power control module 132 described above with reference to FIG. 4, so a detailed description will be omitted.

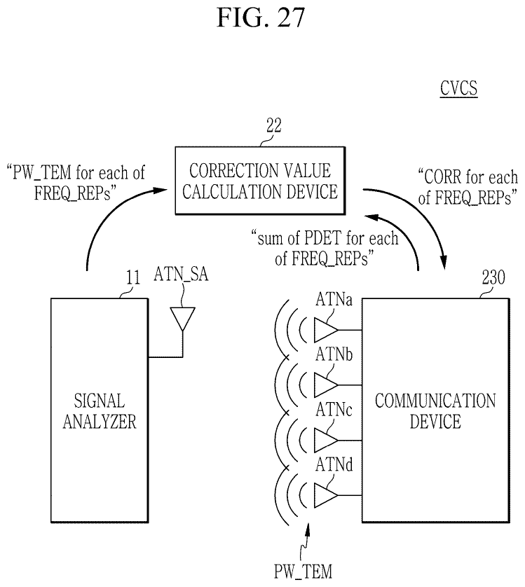

In an embodiment, the representative correction value table CVT_REP and the generalized residual GR may be generated based on a case in which the first to fourth power detection circuits PDCa to PDCd operate simultaneously, unlike those described with reference to FIGS. 1 to 25. A method of generating the representative correction value table CVT_REP will be described with reference to FIG. 27.

The communication power control module 232 may receive the first to fourth detected power values PDETa to PDETd. The communication power control module 232 may estimate the total emission power PW_TEM output through the first to fourth antennas ATNa to ATNd based on the representative correction value table CVT_REP and the first to fourth detected power values PDETa to PDETd. For example, the communication power control module 232 may estimate the total emission power output PW_TEM through the first to fourth antennas ATNa to ATNd by compensating the sum of the first to fourth detected power values PDETa to PDETd based on the compensation correction value CORR_COMP.

The communication power control module 232 may generate the first to fourth gain control signals GCTRLa to GCTRLd based on the estimated total emission power PW_TEM. The communication power control module 232 may provide the first to fourth gain control signals GCTRLa to GCTRLd to the first to fourth amplifiers AMPa to AMPd, respectively, to control the gain of each of the first to fourth amplifiers AMPa to AMPd. In this case, power output from the first to fourth antennas ATNa to ATNd may be adjusted.

FIG. 27 is a diagram illustrating an example correction value calculation system for generating a representative correction value table of FIG. 26. Referring to FIGS. 26 to 27, the correction value calculation system CVCS may include a signal analyzer 11, a correction value calculation device 22, and a communication device 230. The correction value calculation system CVCS may operate in the generation stage of the communication device 230.

The communication device 230 may operate based on an arbitrary representative frequency FREQ_REP. For example, the communication device 230 may simultaneously drive the first to fourth antennas ATNa to ATNd based on the first representative frequency FREQ_REP1.

The communication device 230 may measure the sum of power provided to the first to fourth antennas ATNa to ATNd while driving the first to fourth antennas ATNa to ATNd based on an arbitrary representative frequency FREQ_REP. For example, while the communication device 230 drives the first to fourth antennas ATNa to ATNd based on the first representative frequency FREQ_REP1, the power detection circuit PDC may measure the power of the amplified input signals TX_amp generated from the first to fourth amplifiers AMPa to AMPd to generate the first to fourth detected power values PDETa to PDETd. The communication device 230 may provide a sum of the first to fourth detected power values PDETa to PDETd to the correction value calculation device 22.

For more concise description, FIG. 27 illustrates an embodiment in which the sum of the first to fourth detected power values PDETa to PDETd is provided to the correction value calculation device 22, but the scope of the present disclosure is not limited thereto. For example, the communication device 230 may provide the first to fourth detected power values PDETa to PDETd to the correction value calculation device 22. In this case, the correction value calculation device 22 may calculate a sum of the first to fourth detected power values PDETa to PDETd.

The signal analyzer 11 may measure the total emission power PW_TEM from the first to fourth antennas ATNa to ATNd through the signal analysis antenna ATN_SA. For example, while the communication device 230 drives the first to fourth antennas ATNa to ATNd based on the first representative frequency FREQ_REP1, the signal analyzer 11 may measure the total emission power PW_TEM. The signal analyzer 11 may provide the measured total emission power PW_TEM to the correction value calculation device 22.

The correction value calculation device 22 may calculate the correction value CORR based on the sum of the first to fourth detected power values PDETa to PDETd and the total emission power PW_TEM. For example, when the communication device 230 drives the first to fourth antennas ATNa to ATNd based on the first representative frequency FREQ_REP1, the correction value calculation device 22 may calculate the first representative correction value CORR_REP1 by subtracting the sum of the first to fourth detected power values PDETa to PDETd from the total emission power PW_TEM.

In this way, the correction value calculation device 12 may calculate the first to n-th representative correction values CORR_REP1 to CORR_REPn.

The above-described contents are specific embodiments for carrying out the present disclosure. The present disclosure will include not only the above-described embodiments, but also embodiments that may be simply designed or easily changed. In addition, the present disclosure will also include technologies that may be easily modified and implemented using embodiments. Therefore, the scope of this disclosure should not be limited to the above-described embodiments, but should be determined not only by the scope of the claims to be described below but also by those equivalent to the scope of the claims of this disclosure.

What is claimed is:

1. A communication device controlling an antenna, the communication device comprising:
an amplifier configured to provide, to the antenna, an amplified input signal generated by amplifying an input signal having a target frequency;
a power detector circuit configured to generate a detected power value by detecting a power of the amplified input signal;
a memory circuit configured to store a first representative correction value and a second representative correction value corresponding to a first representative frequency and a second representative frequency, respectively;
an interpolation circuit configured to calculate, based on the first representative correction value and the second representative correction value, a first interpolation correction value corresponding to the target frequency;
a residual compensation circuit configured to read a first generalized residual corresponding to the target frequency from an external memory device and to generate a first compensation correction value based on the first generalized residual and the first interpolation correction value; and
a gain control circuit configured to control a gain of the amplifier based on the first compensation correction value.

2. The communication device of claim 1, wherein:
the first representative frequency is less than or equal to the target frequency, and
the second representative frequency is greater than or equal to the target frequency.

3. The communication device of claim 2, wherein the interpolation circuit is configured to calculate the first interpolation correction value by linearly interpolating the first representative correction value and the second representative correction value.

4. The communication device of claim 1, wherein the gain control circuit is configured to:
estimate emission power from the antenna based on the detected power value and the first compensation correction value; and
control the gain of the amplifier based on the estimated emission power.

5. The communication device of claim 1,
wherein the first representative frequency and the second representative frequency are determined based on first to p-th plurality of feature frequencies, which respectively correspond to first to p-th sample communication devices configured to correspond to the communication device, and
wherein p is an integer greater than or equal to 2.

6. The communication device of claim 5, wherein the first plurality of feature frequencies are determined based on a plurality of ideal correction values, which are respectively calculated for a plurality of frequencies, for the first sample communication device.

7. The communication device of claim 5, wherein the first generalized residual is calculated based on first to p-th correction value residuals, which are calculated for the target frequency, and correspond to the first to p-th sample communication devices, respectively.

8. The communication device of claim 7, wherein the first generalized residual corresponds to an average or a median of the first to p-th correction value residuals.

9. The communication device of claim 7, wherein the first correction value residual corresponds to a difference between:
a second interpolation correction value generated by interpolating a first ideal correction value for the first sample communication device calculated for the first representative frequency, and a second ideal correction value for the first sample communication device calculated based on the second representative frequency, and
a third ideal correction value of the first sample communication device calculated for the target frequency.

10. The communication device of claim 1, wherein:
the memory circuit is implemented with a one time programmable (OTP) memory circuit.

11. An electronic device comprising:
an antenna configured to generate an output signal having a target frequency;
a memory device configured to store a plurality of generalized residuals corresponding to a plurality of frequencies, respectively; and
a communication device configured to control the antenna based on the plurality of generalized residuals,
wherein the communication device comprises:
a memory circuit configured to store a plurality of representative correction values corresponding to a plurality of representative frequencies, respectively;
an interpolation circuit configured to generate an interpolation correction value corresponding to the target frequency based on the plurality of representative correction values;
a residual compensation circuit configured to read a first generalized residual corresponding to the target frequency from among the plurality of generalized residuals, and to generate a compensation correction value based on the first generalized residual and the interpolation correction value; and
a gain control circuit configured to adjust power of the output signal based on the compensation correction value.

12. The electronic device of claim 11, wherein the communication device further comprises:
a signal processing circuit configured to generate an input signal;
an amplifier configured to provide, to the antenna, an amplified input signal generated by amplifying the input signal; and
a power detector circuit configured to generate a detected power value corresponding to a power of the amplified input signal.

13. The electronic device of claim 12, wherein the gain control circuit is configured to:
estimate an emission power corresponding to the output signal based on the detected power value and the compensation correction value; and
adjust a gain of the amplifier based on the estimated emission power.

14. The electronic device of claim 11, wherein:
the plurality of frequencies comprise the plurality of representative frequencies, and
a number of the plurality of generalized residuals is greater than a number of the plurality of representative correction values.

15. The electronic device of claim 11, wherein the interpolation circuit is configured to:
generate the interpolation correction value by linearly interpolating first and second representative correction values respectively corresponding to first and second representative frequencies adjacent to the target frequency among the plurality of representative frequencies.

16. The electronic device of claim 11, wherein:
the residual compensation circuit is configured to generate the compensation correction value by adding the interpolation correction value and the first generalized residual.

17. The electronic device of claim 11, wherein the plurality of generalized residuals are determined based on a plurality of correction value residual tables, which respectively correspond to a plurality of sample communication devices configured to correspond to the communication device.

18. The electronic device of claim 17, wherein:
a first correction value residual table, which is one of the plurality of correction value residual tables, is generated based on a difference between an ideal correction value table and an interpolation correction value table for a first sample communication device among the above plurality of sample communication devices,
the ideal correction value table comprises a plurality of ideal correction values for the plurality of frequencies, and
the interpolation correction value table comprises a plurality of interpolation correction values generated by interpolating ideal correction values corresponding to the plurality of representative frequencies.

19. An operating method of a characteristic analysis device for analyzing characteristics of a plurality of frequencies of a communication device controlling an antenna, the operating method comprising:
generating first to p-th ideal correction value tables based on first to p-th sample communication devices configured to correspond to the communication device, respectively;
identifying first to p-th plurality of feature frequencies based on the first to p-th ideal correction value tables, respectively;
determining first to n-th representative frequencies based on the first to p-th plurality of feature frequencies;
generating first to p-th interpolation correction value tables based on the first to n-th representative frequencies and the first to p-th ideal correction value tables;
generating first to p-th correction value residual tables respectively based on the first to p-th interpolation correction value tables and the first to p-th ideal correction value tables; and
determining a plurality of generalized residuals based on the first to p-th correction value residual tables,
wherein each of n and p is an integer greater than or equal to 2.

20. The operating method of claim 19, wherein the communication device is configured to adjust a power of a signal provided to the antenna based on a compensation correction value generated based on the first to n-th representative frequencies and the plurality of generalized residuals.
